(19) United States
(12) Patent Application Publication
(10) Pub. No.: US 2002/0057592 A1
(43) Pub. Date: May 16, 2002

(54) Distributed storage in semiconductor memory systems

(76) Inventor: David C. Robb, Menlo Park, CA (US)

Correspondence Address: Henneman & Saunders, 121 E. 11th Street, Tracy, CA, 95376, US

(21) Appl. No.: 10/011,184

(22) Filed: Nov. 13, 2001

Related U.S. Application Data
(60) Provisional application No. 60/248,345, filed on Nov. 13, 2000.

(51) Int. Cl. G11C 11/00

(52) U.S. Cl. 365/148

(57) ABSTRACT

A memory device (14) having therein a plurality of memory blocks (10, 30, 80) each having a plurality of storage cells (12). A data vector (20, 20a, 20b), is distributed according to an assignment matrix (16, 90) to the storage cells (12). A reverse assignment matrix (24) can be used to recover the data bits (18). The memory block storage method can be accomplished entirely numerically or using a combination of analog and digital circuitry. Write blocks (40, 100) and recovery blocks (60, 110) are examples of such circuitry.

### TECHNICAL FIELD

The present invention relates to the field of data storage devices, and more specifically to an improved method and construction for improving the capacity and reliability of memory cell devices. The predominant current usage of the present inventive distributed storage method and apparatus is in the construction of semiconductor memory systems, wherein it is desirable to increase the storage capacity and reliability thereof.

### BACKGROUND ART

Initially, memory cells were designed to store a single bit in each storage location. Some of the earliest solid state systems used several transistors to form a latch. The latch would retain the value of a bit written to it as long as power was applied to the circuit. While effective, this approach was also expensive since it used several transistors per bit. It was also volatile in that data would not be retained once power was removed.

Semiconductor manufacturers attacked these and other problems in a variety of ways. Eventually, a way was found to reduce the size of a memory cell to the size of a single transistor. Unfortunately, the mechanism was still volatile, and in the case of dynamic memories, data stored would decay with time, and needed to be refreshed periodically. It still “forgot” when power was removed.

Another direction yielded flash memories which relied on charge stored in an electrically isolated gate to indicate the bit value. Charge would be placed on the gate by a process called tunneling whereby electrons would be induced to cross what would normally be an impenetrable energy barrier of the insulating layer. Charge thus emplaced would remain in place for hundreds or thousands of years—effectively forever. This could be done with single transistor structures, which meant that high storage densities could be achieved. Unfortunately, the process of emplacing and removing charge would ultimately degrade the insulator so that the life of flash cells would be limited to 10,000 to 1,000,000 write operations, which is insufficient for general storage applications but more than ample for many uses where only a few thousand write cycles were required over the useful life of the product.

In 1992, researchers started work on designs which would allow storage of more than one bit in a cell. Part of the impetus for such work was the fact that the single transistor storage cells were now so small that their size was limited by the lithography process, not by the electrical constraints. Thus increases in storage density would come most rapidly from multibit storage approaches, and only slowly from advances in the lithographic processes. A prototype multibit device was developed in 1994. The multibit storage was implemented by precise storage of charge on the isolated gate so that multiple levels of charge could be accurately placed and sensed. A two bit per cell design, for example, required the ability to place and sense four different charge levels. Three bits would require eight, and four bits would need 16 levels.

Current state-of-the-art memories use two bits per cell, or four storage levels. The difficulties inherent in charge placement and sensing for eight and sixteen levels have proven to be sufficiently difficult that commercial production of such devices is still out of reach.

It would be desirable to have a method and or means for increasing the storage density of semiconductor memory devices and/or improving the reliability thereof. However, to the inventor's knowledge, the current status of such devices is as described and discussed above.

### DISCLOSURE OF INVENTION

Accordingly, it is an object of the present invention to provide a method and apparatus for potentially increasing the storage density in semiconductor memory devices.

It is another object of the present invention to provide a method and apparatus for improving the read back reliability in semiconductor memory devices.

It is still another object of the present invention to provide a method and apparatus for improving semiconductor memory devices which is easy and inexpensive to implement.

Briefly, a known embodiment of the present invention is a single bit per cell system which has significant advantages in terms of device yield in production. This embodiment uses the current single cell with isolated gate structure employed in prior art designs. It also uses the current ability to place precise quantities of charge on the gate, as well as the ability to sense, with reasonable error, that quantity of charge. However, in the described embodiment of the invention, the charge associated with a bit is divided into several parts. Charge units from several bits are combined and the composite charges are stored in a set of cells. The charge from each bit is distributed across multiple cells, and each cell is shared among a set of bits. The number of bits sharing a cell is limited so that the total charge in a cell never exceeds the total undivided charge for a single bit. The pattern of charge distribution is managed so that each bit can be recovered uniquely. A pre-determined assignment matrix is calculated prior to design of the memory system, and becomes part of the design. The assignment matrix indicates which cells will receive a unit charge for each of the input bits.

A second described embodiment of the present invention is a multi-bit per cell design. This embodiment forms first level storage sums as in the single bit approach described above, then combines two or more first level storage sums to obtain a final sum. The final sum is the actual value stored.

A third described embodiment of the invention forms a multi-level multi-bit value, essentially equivalent to that produced by a binary DAC. These multi-level values are then combined to form the storage values.

These and other objects and advantages of the present invention will become clear to those skilled in the art in view of the description of modes of carrying out the invention, and the industrial applicability thereof, as described herein and as illustrated in the several figures of the drawing. The objects and advantages discussed herein are not an exhaustive list of all possible advantages of the invention. Moreover, it will be possible to practice the invention even where one or more of the intended objects and/or advantages might be absent or not required in the application.

Further, those skilled in the art will recognize that various embodiments of the present invention may achieve one or more, but not necessarily all, of the above described objects and/or advantages. Accordingly, the listed advantages are not essential elements of the present invention, and should not be construed as limitations.

### BRIEF DESCRIPTION OF THE DRAWINGS

FIG. 1 is a diagrammatic representation of a memory block, according to one example of the present invention;

FIG. 2 is an example of a memory device such as might be used to practice the present invention;

FIG. 3 is a diagrammatic representation of an example of a numerical assignment matrix according to one embodiment of the present invention;

FIG. 4 is an example of a single bit per cell memory block according to one embodiment of the present invention;

FIG. 5 is a continuation of the example of FIG. 4 showing a second data bit distributed to the single bit memory cell;

FIG. 6 is a further continuation of the example of FIG. 4, showing a third data bit distributed to the single bit memory cell;

FIG. 7 is an example of a reconstruction of a single bit per cell memory block, according to one embodiment of the invention;

FIG. 8 is a continuation of the example of FIG. 7, showing the reconstruction of a second data bit;

FIG. 9 is a block diagram of a first example of a multi bit per cell memory block;

FIG. 10 is a block schematic diagram depicting a hardware means for accomplishing the example of FIG. 9;

FIG. 11 is a block schematic diagram, similar to that of FIG. 10, depicting a prior art apparatus for comparison to the inventive apparatus of FIG. 10;

FIG. 12 is a block schematic diagram depicting a hardware means for accomplishing a multi bit per cell recovery operation, according to the present inventive method;

FIG. 13 is a block schematic diagram, similar to that of FIG. 12, depicting a prior art apparatus for comparison to the inventive apparatus of FIG. 12;

FIG. 14 is a diagrammatic representation of a second example of a multi bit per cell memory block;

FIG. 15 is an alternative assignment matrix illustrating the method associated with the example of FIG. 15;

FIG. 16 a block schematic diagram depicting a hardware means for accomplishing the example of FIG. 14; and

FIG. 17 is a block schematic diagram depicting a hardware means for accomplishing a multi bit per cell recovery operation, according to the example of FIG. 14.

### DETAILED DESCRIPTION OF THE INVENTION

The embodiments and variations of the invention described herein, and/or shown in the drawings, are presented by way of example only and are not limiting as to the scope of the invention. Unless otherwise specifically stated, individual aspects and components of the invention may be omitted or modified, or may have substituted therefore known equivalents, or as yet unknown substitutes such as may be developed in the future or such as may be found to be acceptable substitutes in the future. The invention may also be modified for a variety of applications while remaining within the spirit and scope of the claimed invention, since the range of potential applications is great, and since it is intended that the present invention be adaptable to many such variations.

An example of the present invention is an improved single bit per cell memory block which is shown in the block diagram of FIG. 1, and designated therein by the general reference character 10. This particular example of the single bit per cell memory block 10 has sixteen memory locations (“cells”) 12. It should be noted that this quantity of cells 12 is presented here by way of example only, and that the present invention could be practiced using generally any quantity of cells 12 which is compatible with the aspects of the invention discussed hereinafter.

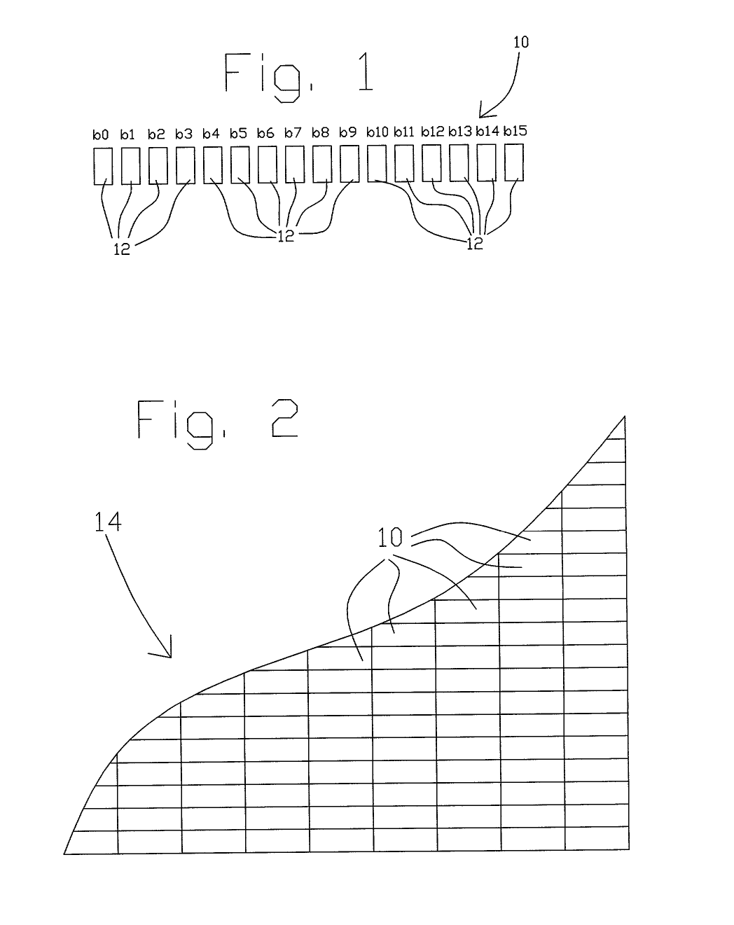

FIG. 2 is a block diagrammatic representation of a portion of a memory device 14 having therein a large plurality of the memory blocks 10. The memory device 14 is physically of the current type known in the prior art, with isolated gate structure employed in conventional prior art designs. The memory device 14 uses the current ability to place precise quantities of charge on the gate thereof, as well as the ability to sense, with reasonable error, that quantity of charge. It should be noted that the division of the memory device 14 into the memory blocks 10 is depicted here merely to indicate that such theoretical division is possible, and that such divisions will be used herein to explain the operation of the invention. One skilled in the art will recognize that the memory device 14 might optionally be divided into word and/or memory block divisions, according to the particular type of physical device to be used in conjunction with the invention.

As will be discussed in more detail hereinafter, in the single bit per cell memory block 10 of FIG. 1, the charge associated with a bit is divided into several parts. Charge units from several bits are combined and the composite charges are stored in a set of cells 12. The charge from each bit is distributed across multiple cells 12, and each cell 12 is shared among a set of bits. The number of bits sharing a cell 12 is limited so that the total charge in a cell 12 never exceeds the total undivided charge for a single bit. The pattern of charge distribution is managed so that each bit can be recovered uniquely.

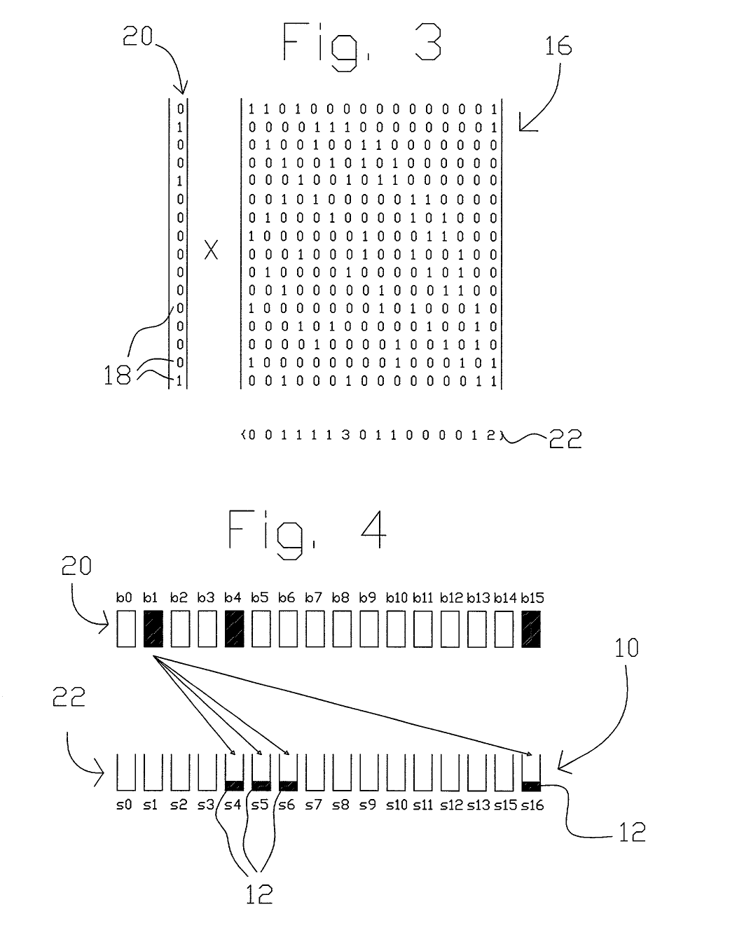

FIG. 3 is an example of a pre-determined assignment matrix 16 such as might be used to accomplish the described embodiment of the invention. The assignment matrix 16 indicates which cells 12 (FIG. 1) will receive a unit charge for each of a plurality of data bits 18 (FIG. 1). The example of the assignment matrix 16 shown is a 16 by 16 matrix wherein each row is associated with a particular bit 18 input, and each column is associated with a storage location (cell 12). Wherever a “1” appears in the matrix 16, a unit charge for that bit 18 is added to the indicated cell 12, as will be described in more detail hereinafter.

The example of the matrix 16 shown in FIG. 3 has a four-fold redundancy. That is, there are four copies of each bit 18 distributed among the sixteen cells 12 (as indicated by the fact that there are four iterations of the numeral “1” in each row). An example of how sixteen bits of data would be redundantly stored is shown beginning in FIG. 4. An example data vector 20 is merely an example of a data series, chosen essentially at random, to be used to illustrate an example of storage of the data therein, as will be discussed hereinafter. To provide consistency in this example, the data in the data vector 20 is that shown in the example of the data bits 18 of FIG. 3. As illustrated in the view of FIG. 4, the data vector 20 has sixteen data bits. According to the present invention, the data vector 20 is multiplied times the A matrix 16 (FIG. 3) to give an storage vector 22, which is the vector of values which will actually be stored in the sixteen storage cells 12. In the example of FIG. 4, the charge from a b1 bit 18a is shown distributed among the appropriate cells 12 of the memory block 10, according to the assignment matrix 16 of FIG. 3.

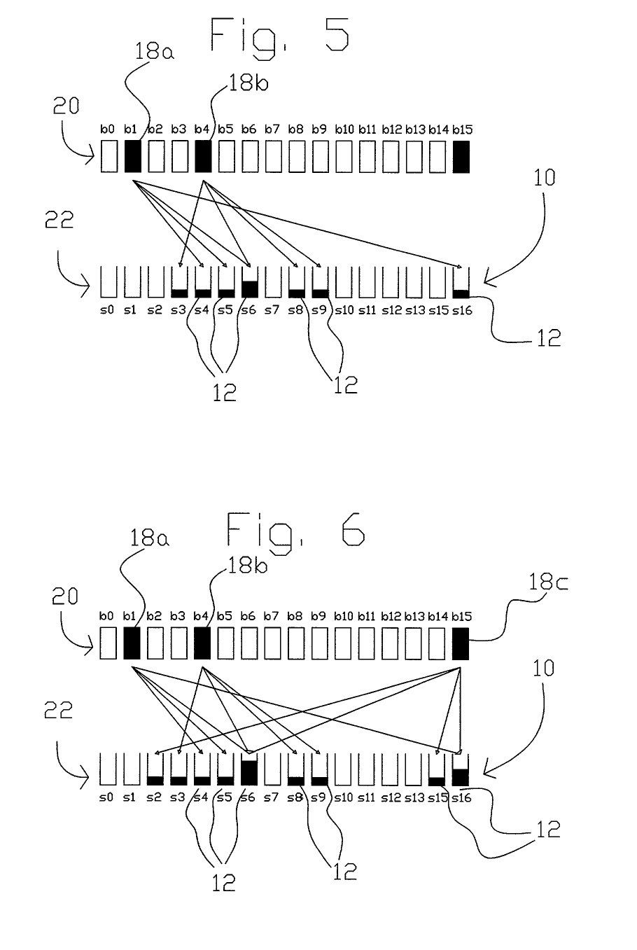

FIG. 5 is a block diagram, similar to that of FIG. 4, showing the additional charges from a b4 data bit 18b distributed according to the assignment matrix 16 of FIG. 3. FIG. 6 is yet another block diagram, similar to that of FIGS. 4 and 5, showing the additional charges from a b15 data bit distributed according to the assignment matrix 16 of FIG. 3. It should be noted that the data bits 18a, 18b and 18c correspond to the “1” entries in the data bits 18 vector of FIG. 3. Therefore, the example of FIGS. 4, 5 and 6 correspond to the example of the data used in FIG. 3.

One skilled in the art will recognize that the charge provided to each of the storage cells 12, in the example given above, will be one quarter of the total allowable charge for each cell. For example, if the maximum charge allowed for a cell 12 were 10,000 electrons, then with the four-fold redundancy of the present example, each unit of charge would be 2,500 electrons. Therefore, no cell 12 will be required to store more that its capacity of 10,000 electrons, the same amount that it would store using a conventional approach to data storage. However, unlike a conventional approach, according to the present invention, an entire cell 12 can be lost and the data vector 20 still recovered. Further, the present inventive method is highly resistant to “noise” in the form of variability in the stored values.

According to the present inventive method, recovery of the data vector 20 (the original data) can be accomplished in several ways. One of the simplest is to multiply the storage vector 22 by the inverse of the assignment matrix 16. This will give the original bit values. As described previously herein, if the storage values have been corrupted by noise, then the recovered bit estimates may be recovered using a binary decision process, such as rounding.

A second approach would be to recursively estimate the bit vector, calculate an estimate of the storage values resulting from that estimated bit vector, compare it to the actual storage values, and refine the estimate until the error between the estimated storage values and the actual storage values is minimized. This approach is simple to implement in hardware, and is quite robust in practice. One skilled in the art will be familiar with this approach to implementation in hardware.

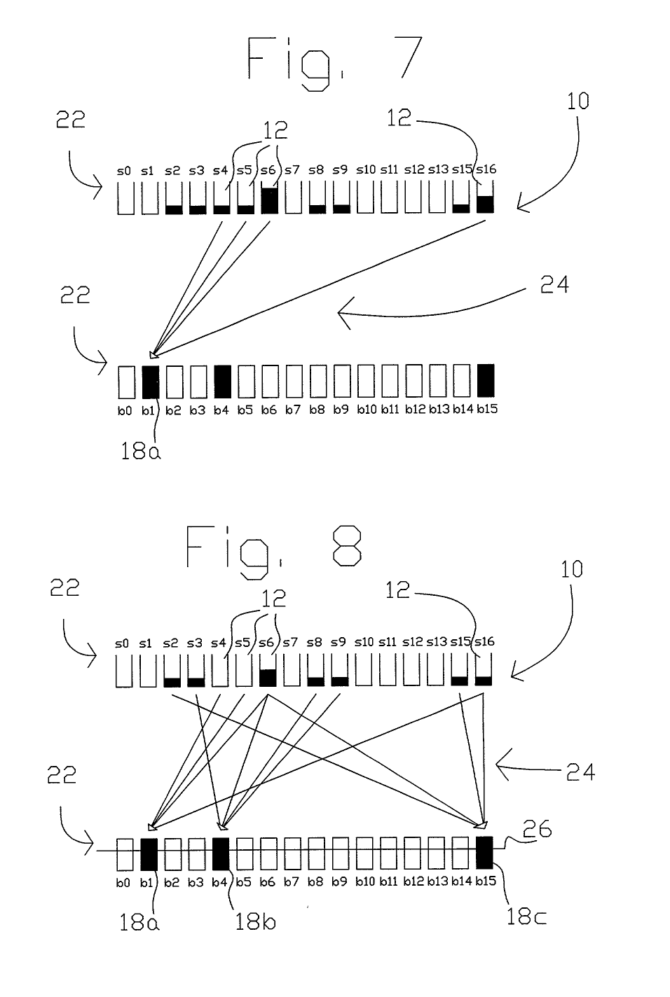

FIG. 7 is the first in a series of diagrammatic representations illustrating the recovery of the data vector 20. As can be seen in the view of FIG. 7, the b1 data bit 18a is reconstructed from where the charges were stored in the original storage operation previously discussed herein. A reverse assignment matrix 24 is indicated by the lines in FIG. 7 showing from where the charge is drawn in the storage cells 12 of the memory block 10 to reconstruct the b1 data bit 18a. In like fashion, FIG. 8 illustrates a continuation of the reconstruction process, wherein all three of the “1” data bits of the data vector 20 are shown as reconstructed. In the view of FIG. 8 can be seen an example of a recovery threshold 26. As can be appreciated in light of the above discussion, even if one of storage cells 12 were to fail completely, the data of the data vector 20 could still be accurately recovered, since the recovery threshold 26 the recovered charge would still be greater than required by the recovery threshold 26 if one quarter of the total charge were missing.

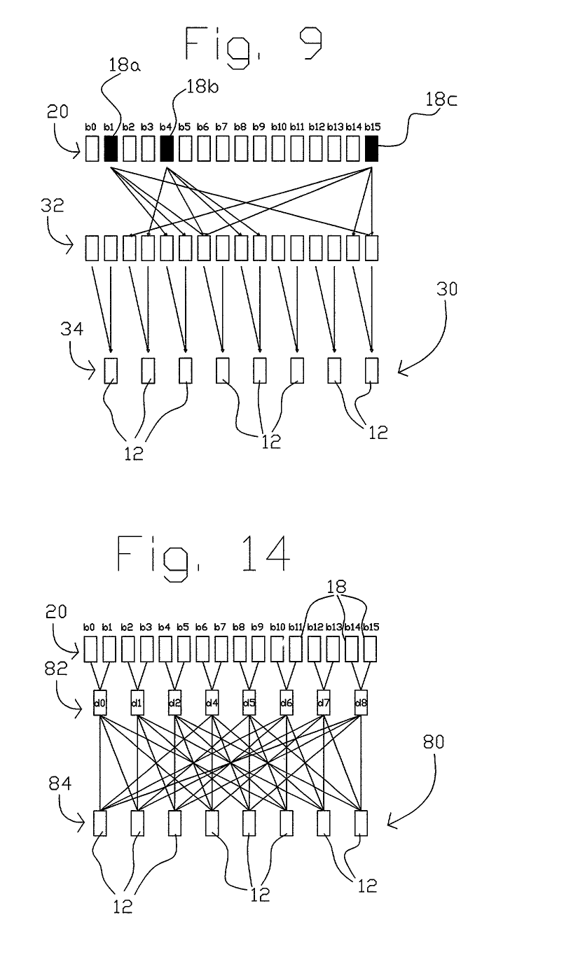

FIG. 9 is a diagrammatic example of a first multi bit per cell memory block 30 implemented according to the present invention. In the multi bit per cell memory block 30, a plurality of first level storage sums (“S values”) 32 are calculated in the manner previously described herein in relation to the storage vector 22 of the previously described embodiment 10 of the invention. Then, two or more (two, in the example of FIG. 9) of the S values 32 are combined to form a storage sum (“C value”) 34, and each of the C values 34 is stored in a corresponding cell 12. That is, the C values 34 are calculated as follows:

Cⱼ=S_{Kj}+N·S_{Kj+1}+N²·S_{Kj+2}+ . . . +N^{K-1}·S_{Kj+K-1}

where: C is the combination value (C value 34), S is the sum as in the single bit per cell above (S value 32), N is the number of bits combined into each sum (as discussed previously herein in relation to the first described embodiment of the invention), and K is the number of bits per cell (two, in the example of FIG. 9, as discussed previously herein), and i is an index.

In the diagram of FIG. 8, the exact values of the first level storage sums 32 are not shown, nor are the values of the final storage sums. These will be discussed in greater detail hereinafter. Also, it should be noted that all of the lines representing the assignment matrix 16 are not shown, as doing so would make the diagram overly complex. Rather the assignment matrix 16 is represented in the view of FIG. 8, as in the previously discussed examples, only by those lines which represent the portion of the assignment matrix 16 where there are “1” values to be distributed.

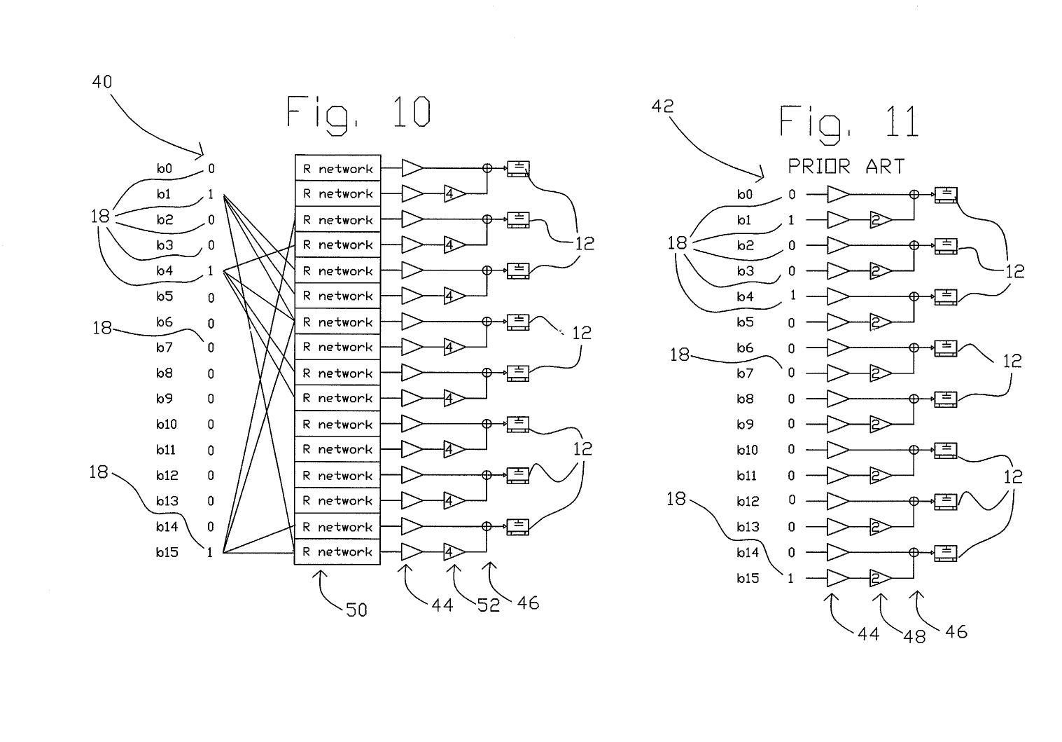

One skilled in the art will recognize that the above described general method (indeed, essentially any of the methods described herein as being aspects of the present invention) can be accomplished in an entirely digital fashion (as by numerically accomplishing the formulas recited herein). Alternatively, it will be recognized that these methods may also be accomplished in using a combination of digital and analog circuitry. For example, FIG. 10 is a block schematic diagram depicting a write block 40, which is an example of a hardware means for accomplishing the example of FIG. 9. FIG. 11 is a block schematic diagram, similar to that of FIG. 10, depicting a prior art write apparatus 42 for comparison to the inventive apparatus of FIG. 10. As can be seen in the view of FIG. 11, and as well be well known to one skilled in the art, in order to achieve multi bit per cell storage in the prior art, pairs of the data bits 18 are buffered in buffer amplifiers 44 and summed in a plurality (eight, in this present example) of summing devices. As one skilled in the art will recognize, one of each pair is amplified in a 2×amplifier 48 so that the appropriate data bits can be distinguished upon reconstruction thereof. By comparison, in the example of the inventive write block 40 of FIG. 10, the data bits 18 are apportioned into a plurality of resistor networks 50 before processing through the buffer amplifiers 44 and the summing devices 46. In the example of FIG. 4, a plurality of 4×amplifiers are used so that the data can later be recovered, as will be discussed in more detail hereinafter. In the example of FIG. 10, as in prior examples, only a few examples of the lines showing distribution of data bits 18 to the resistor networks 50. The remainder of the lines could easily be filled in using the data in the assignment matrix of FIG. 3.

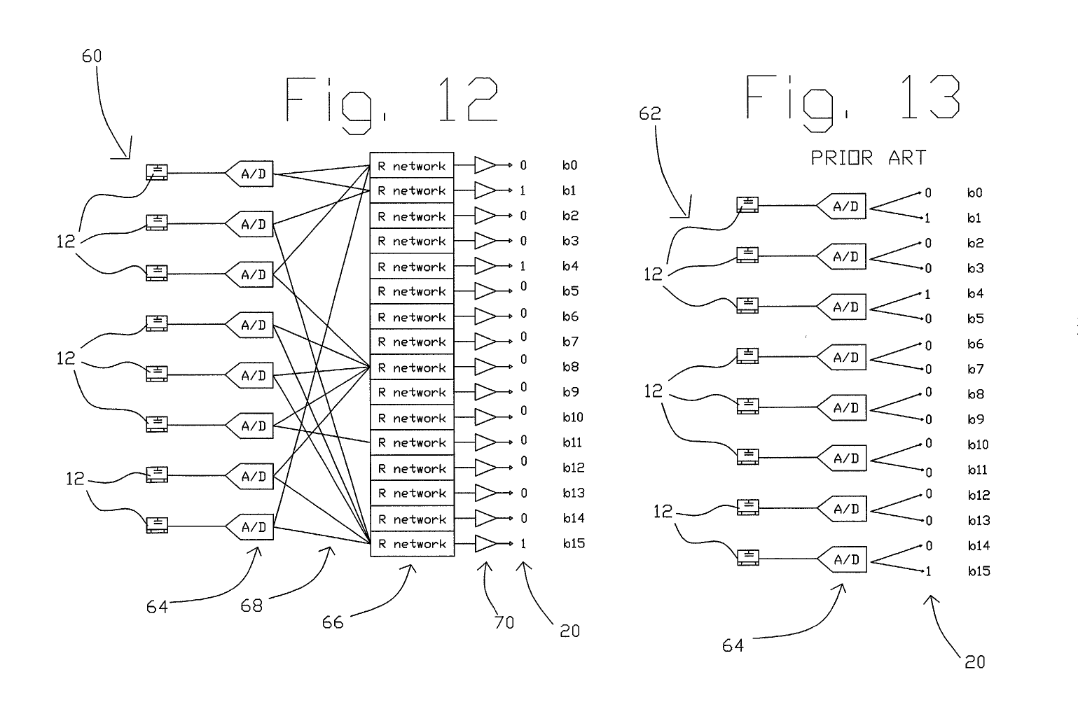

One example of a way to recover the bit values stored according to the first multi bit per cell memory block 30 example is to solve the equation discussed above recursively working from the rightmost term in the equation backward. Using modulo division in powers of N will give each sum term, with the remainder (the modulo result) is the value in the next recursion. As discussed previously, herein, an inverse matrix approach can also be used to recover the data. A hardware approach is illustrated by an example of a hardware recovery block 60 which is depicted in block diagrammatic form in FIG. 12. FIG. 13 is an example of a prior art read apparatus 62, which is included here for purposes of comparison only. One skilled in the art will recognize that the read apparatus 62 has a plurality (one per data cell 12) of analog to digital (“A/d”) converters which recover the data vector in the manner previously discussed herein in relation to the prior art. In a similar manner the inventive recovery block 60 uses the A/D converters initially. However, in this example of the invention, the output of the A/D converters 64 is provided to a resistor network 66 in a manner indicated by the inverse of the assignment matrix 16 (FIG. 3). In the example of FIG. 12, only a few of the connecting lines 68 are shown, for purposes of example only. In the example of FIG. 12 can also be seen a plurality (one per resistor network 66) of output buffer amplifiers 70 which output the data vector 20.

One skilled in the art will recognize that the first multi bit per cell memory block 30 is a relatively simple modification of the method described in relation to the single bit per cell memory block 10 previously discussed. While this embodiment has the advantage of being simple to implement, it does have the drawback that the storage system is now vulnerable to single point failure, as each cell 12 uniquely contains two or more sums.

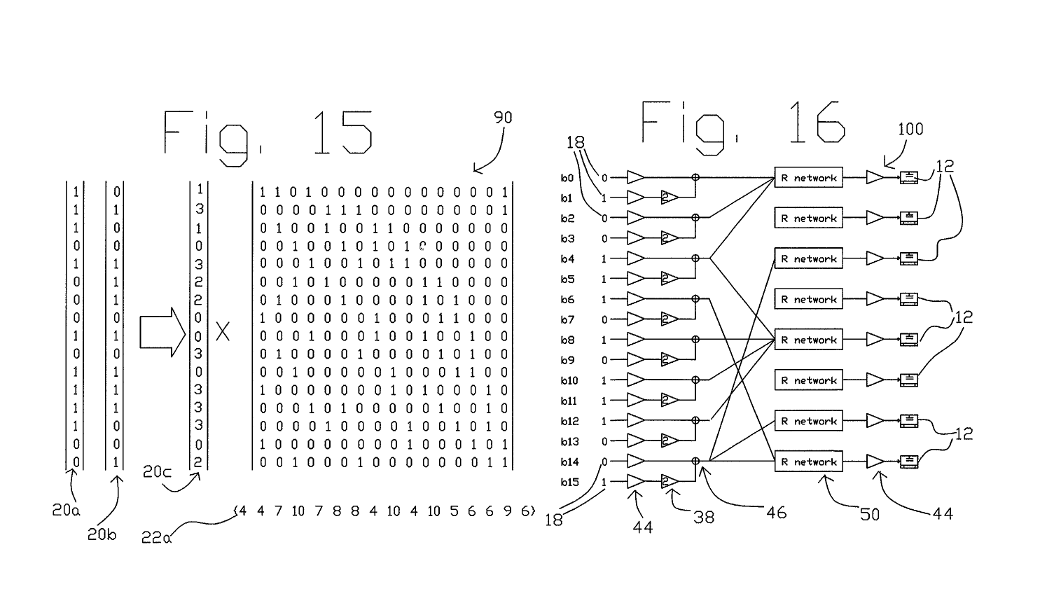

FIG. 14 is a diagrammatic representation of a second multi bit per cell memory block 80. Like the first described single bit per cell memory bock 10, the second multi bit per cell memory block 80 can potentially withstand the loss of an entire cell 12 without loss of data (in at least some embodiments), since the sums are distributed across multiple storage locations (cells 12). In the second multi bit per cell memory block 80, two or more bits are combined to form a composite value (“D value”) 82. The D value 82 is then distributed across multiple cells 12 in the same manner as the bits are distributed in the single bit per cell memory block 10 described previously herein. The number of data bits 18 combined to form the composite D value 82 is equal to the number of bits per cell to be stored. Therefore, the composite D value 82 is formed as follows:

Dⱼ=b_{Kj}+2·b_{Kj+1}+2²·b_{Kj+2}+ . . . +2^{K-1}·b_{Kj+K-1}

where: D is the composite D value38, K is the number of bits per cell 12, and b is the bit value (0 or 1 in a binary system). A plurality of storage S values 84 are then calculated as follows:

S=D·A

where S is the S value 84, D is the D value 82 and A is an assignment matrix (like the Assignment Matrix 16 of FIG. 3).

Another way of illustrating this same method is depicted by the second assignment matrix 90 of FIG. 15. As can be seen in the view of FIG. 15, data from a first binary input vector 20a and a second binary input vector 20b is first initially combined to form a multi level input vector 20c. Then the multi level input vector 20c is multiplied by the assignment matrix 90 to produce a multi level sums vector 22a, which is then stored in the cells 12.

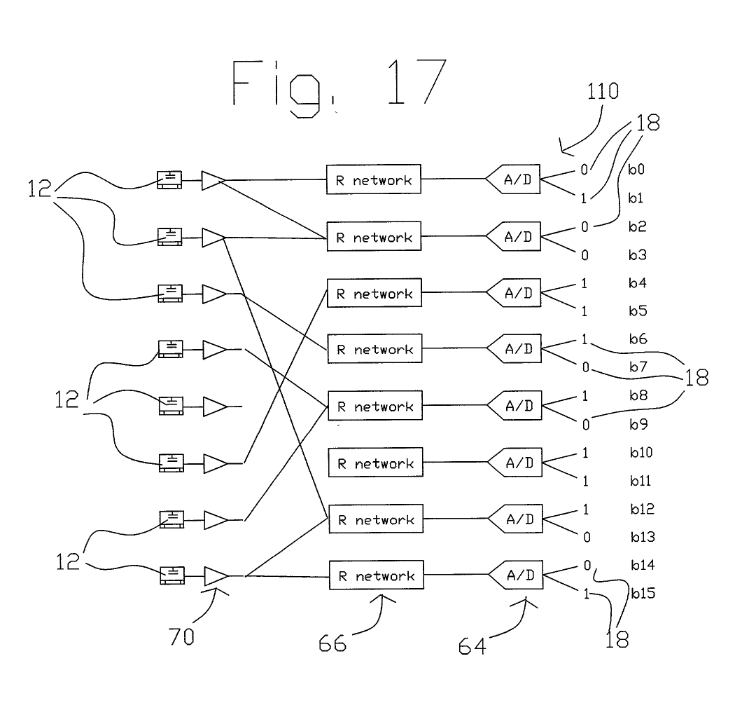

FIG. 16 is block schematic diagram of a write block 100 illustrating a hardware means for accomplishing the method described above in relation to the example of FIGS. 14 and 15. As can be seen in the view of FIG. 16, the data bits 18 are first combined (in pairs, in this present example) through a plurality of buffer amplifiers 44 and summing devices 46. As in the prior art, one of the 2×amplifiers 48 is used on one of each of the pairs of the data bits 18 so that the data can be differentiated when the charge on the cells 12 is eventually read back. Then, according to this example of the invention, the result of the combination of the pairs of data bits 18 is distributed as described above to the cells 12 through the resistor networks 50 and additional buffer amplifiers 44.

Recovery of the data can be effected by several methods. One is to first recover the composite values by multiplying the storage vector by the inverse of the A assignment matrix 16, 90, or equivalent. Each composite D value 82 is then solved for the particular bit values of which it is composed. An alternative method would be to electrically accomplished this process by using summing amplifiers with input weights equal to the corresponding values in the inverse of the A matrix 16, 90, or the like. The output of each summing amplifier is then the storage value, which can be converted to bit values by a simple K-bit analog to digital converter (“ADC”).

Still another alternative approach would be to calculate estimates of each of the N composite D values 82, and then sum them. One skilled in the art will recognize that this would be relatively easy to implement in hardware, and would reduce the overall error due to device variability and tolerances. The individual bit values can be obtained by a K-bit ADC, or by estimation and feedback circuitry.

A read block 110 in FIG. 17 illustrates a hardware method for accomplishing the recovery of the data bits 18. As can be seen in the view of FIG. 17, the content of the cells 12 is distributed to the resistor networks 66 according to the inverse matrix method described above. Then, a plurality of analog to digital converters separate each of the pairs of data bits 18 in like manner to the prior art example discussed previously herein.

Various modifications may be made to the invention without altering its value or scope. For example, the matrices 16, 90 used by way of example herein, are examples only. One skilled in the art will be able to construct a great many assignment schemes which will accomplish the present invention. Further, the redundancies, quantity of cells 12 per block 10, 20, 90, and essentially all numerical variables described herein could be varied while keeping within the objects and scope of the present invention.

All of the above are only some of the examples of available embodiments of the present invention. Those skilled in the art will readily observe that numerous other modifications and alterations may be made without departing from the spirit and scope of the invention. Accordingly, the disclosure herein is not intended as limiting and the appended claims are to be interpreted as encompassing the entire scope of the invention.

### Industrial Applicability

The inventive memory blocks 10, 30 and 80 and associated methods for storing and retrieving data are intended to be widely used in the production of memory devices, and in particular solid state memory devices. There are several advantages to distributing the charge associated with a bit among multiple cells. As discussed previously herein, a primary advantage is that single cell failures can be tolerated. As discussed above, at least in some embodiments of the invention a single cell can fail to retain charge and give a completely erroneous result and it will still be possible to obtain the data that was stored, since the information exists in redundant copies.

Since a large portion of failures in memory arrays are in the form of single point failures due to point defects, the ability to tolerate defects should give dramatic improvement in yields, and will reduce the necessity to add redundant cells and logic elements for error detection and correction.

Another advantage which is inherent in the invention is that the distribution of charge reduces error in estimation of the bit value by reducing variability effects of cells. It is well known in statistics that averaging reduces the error of the estimate by the root of the number of samples. The error in charge in one cell is typically offset by opposing errors in the other cells. Consequently, greater error in an individual cell value can be tolerated, reducing the performance requirements of the circuitry.

These advantages will potentially translate into further advantages in terms of memory design. In some designs, the size of the physical storage cell can be reduced. This will often have the effect of increasing variability and error rate in conventional designs, but these can be offset by the gains of the inventive technology. This leads to more die per wafer, improved yields of good die, and corresponding cost reductions or greater profits.

Since the memory blocks 10, 30 and 80 and associated methods for storing and retrieving data of the present invention may be readily produced using known manufacturing methods and operations, and since the advantages as described herein are provided, it is expected that it will be readily accepted in the industry. For these and other reasons, it is expected that the utility and industrial applicability of the invention will be both significant in scope and long-lasting in duration.

I claim:

1. What is claimed is:
A method for storing data in a plurality of storage locations, comprising:
dividing each of a plurality of bits into a plurality of bit subparts; and
storing at least some of said bit subparts into at least some of a plurality of the storage locations.

2. The method of claim 1, and further including:
combining at least some of said bit subparts prior to storing said bit subparts in said storage locations.

3. The method of claim 2, wherein:
said bit subparts are combined in pairs.

4. The method of claim 1, and further including:
combining at least some of said bits prior to dividing said bits.

5. The method of claim 4, wherein:
said bits are combined in pairs.

4. The method of claim 1, wherein:
said storage locations are charge storage locations.

5. The method of claim 1, wherein:
said storage locations are cells in a solid state memory device.

6. The method of claim 1, wherein:
each of said bit subparts is a charge equivalent to a fraction of a total charge which can be held in each of said storage locations.

7. The method of claim 1, wherein:
each of said bit subparts is equivalent to one quarter of a total charge which can be held in each of said storage locations.

8. The method of claim 1, wherein:
said bit subparts are stored in said storage locations according to an assignment matrix.

9. The method of claim 8, wherein:
said assignment matrix is an eight by eight matrix.

10. The method of claim 1, and further including:
recombining said bit subparts to reconstruct said bits.

11. The method of claim 10, wherein:
said bits are recombined according to a reverse matrix.

12. A data storage apparatus for storing a plurality of data bits, comprising:
a plurality of data storage locations;
a directing apparatus for directing portions of each of said data bits into more than one of said data storage locations.

13. The data storage apparatus of claim 12, wherein:
said directing apparatus includes a predetermined assignment matrix for assigning said portions to said storage locations.

14. The data storage apparatus of claim 12, wherein:
said directing apparatus includes a plurality of hard wired paths for directing said portions.

15. The data storage apparatus of claim 12, wherein:
said directing apparatus includes a resistor network for dividing the bits into said portions.

16. The data storage apparatus of claim 12, wherein:
said directing apparatus includes a digital to analog converter for converting said bits into an analog format.

17. The data storage apparatus of claim 12, and further including:
a data reconstruction apparatus for directing said portions into said bits.

18. The data storage apparatus of claim 12, wherein:
said data storage locations are cells in a solid state data storage array.

19. A data storage apparatus for storing a plurality of data bits, comprising:
a plurality of data storage locations; and
directing means for directing portions of each of said data bits to two or more of said data storage locations.

20. The data storage apparatus of claim 19, wherein:
said directing means includes an assignment matrix for determining which of the portions are directed to which of said data storage locations.

21. The data storage apparatus of claim 20, wherein:
said directing means includes permanent connections for channeling the portions to said data storage locations.
